(19) United States
(12) Patent Application Publication
(10) Pub. No.: US 2010/0270552 A1
(43) Pub. Date: Oct. 28, 2010

(54) THIN FILM TRANSISTOR SUBSTRATE AND METHOD OF MANUFACTURING THE SAME

(76) Inventors: Ki-Yong Song, Seoul (KR); Sung-Haeng Cho, Cheongwon-gun (KR); Jae-Hong Kim, Seoul (KR); Sung-Hen Cho, Seoul (KR); Yong-Mo Choi, Osan-si (KR); Hyung-Jun Kim, Yongin-si (KR); Sung-Ryul Kim, Cheonan-si (KR); Byeong-Hoon Cho, Seoul (KR); O-Sung Seo, Seoul (KR); Seong-Hun Kim, Seoul (KR)

Correspondence Address: Innovation Counsel LLP, 21771 Stevens Creek Blvd, Ste. 200A, Cupertino, CA, 95014, US

(21) Appl. No.: 12/571,323

(22) Filed: Sep. 30, 2009

(30) Foreign Application Priority Data
Apr. 27, 2009 (KR) 10-2009-0036667

(51) Int. Cl. H01L 33/00; B32B 37/00; C23F 1/00

(52) U.S. Cl. 257/59; 156/60; 216/24; 438/30; 438/158; 257/E33.053

(57) ABSTRACT

A protrusion of dry-etched pattern of a thin film transistor substrate generated due to a difference between isotropy of wet etching and anisotropy of dry etching is removed by forming a plating part on a surface of the wet etched pattern through an electroless plating method. If the plating part is formed on a data pattern layer of the substrate, the width or the thickness of the data pattern layer may be increased without loss of aperture ratio, the channel length of the semiconductor layer may be reduced under the limit according to the stepper resolution and the protrusion part of the semiconductor layer may be removed. As a result, the aperture ratio may be increased, the resistance may be reduced, and the driving margin may be increased due to rising of the ion current. Furthermore, the so-called water-fall noise phenomenon may be eliminated.

### CROSS-REFERENCE TO RELATED APPLICATION

This application claims priority under 35 U.S.C. §119 to Korean Patent Application No. 10-2009-0036667, filed on Apr. 27, 2009 in the Korean Intellectual Property Office (KIPO), the contents of which are herein incorporated by reference in their entirety.

### BACKGROUND OF THE INVENTION

(a) Field of the Invention

The present invention relates to a thin film transistor substrate and the method of manufacturing the same, and more particularly, to a thin film transistor substrate including a plating part and the method of manufacturing the same.

(b) Description of the Related Art

An LCD (Liquid Crystal Display) using the birefringence characteristic of a liquid crystal molecule have taken the position of the most competitive flat panel display by improving its performance and reducing manufacturing cost continuously since its commercial possibility was first announced as DS (Dynamic Scattering) mode.

Brightness, contrast ratio, resolution, display quality of moving picture, viewing angle, color reproducibility, power consumption, and so forth can be enumerated as characteristic elements of the LCD. Recently, market needs for higher resolution, higher display quality of moving picture and lower power consumption have increased. In terms of resolution, Full HD (High Definition, 1920×1080) products have been commercialized and R&D about UD (Ultra Definition, 3840×2160) products and further UHD (Ultra High Definition, 7690×4320) products is currently proceeding with activity. In terms of display quality of moving picture, 120 Hz fast driving products and 240 Hz fast driving products have been commercialized and R&D about 480 Hz fast driving products is now proceeding briskly. In terms of power consumption, the so-called green products which reduce power consumption by about ½ compared to prior products having the same size have been released, and efforts for further saving power consumption are in progress continuously through making a back light and a panel more efficient and maximizing aperture ratio and transmission rate.

Meanwhile, efforts for reducing manufacturing cost is also continuously in progress for maintaining price competitiveness of the LCD against other displays. In the case of a TFT (Thin Film Transistor) substrate which is a component of the LCD, a four-mask manufacturing process which completes the TFT substrate by executing a photolithography process four times has been commercialized but efforts continue for reducing the number of times a photolithography process is required.

Efforts for making resolution higher and driving time faster is gradually reaching technical limits due to the low mobility of amorphous silicon which is used in the channel of a switching element in an active matrix LCD. Therefore, industry and the academic world have made various attempts to overcome the technical limits from a material and design point of view. In terms of material, many attempts have been made to use LTPS (low temperature poly silicon) TFT, oxide TFT, or organic TFT as a switching element, but nothing has reached commercialized level for a big size panel. In terms of design, attempts for increasing ion current by increasing channel width or reducing channel length are in progress. In the case of increasing channel width, there is a problem that aperture ratio is reduced and display quality is deteriorated due to a rise of kickback voltage according to an increase of a capacitance between a gate electrode and a source electrode (Cgs). In the case of reducing channel length, it is very difficult to go forward because of its dependency on stepper resolution.

Meanwhile, in the case of the LCD manufactured by the four-mask manufacturing process, a semiconductor pattern layer is formed on and adhered to the whole bottom surface of a data pattern layer. However, the semiconductor pattern layer protrudes in comparison with the data pattern layer due to isotropic characteristics of wet etching and etch-back process. The protrusion of the semiconductor layer disadvantageously reduces aperture ratio and increases wire resistance. In addition, because of the protrusion, the semiconductor pattern layer is exposed to an ambient light so that a brighter region and a darker region are perceived on a picture, which occurs as a result of charging rates of liquid crystal capacitors being varied according to back light dimming because amorphous silicon semiconductor is a material of which the conductivity is changed as a function of intensity of exposing light. Especially in the case that the backlight dimming cycle and panel scanning cycle are not synchronized, the problem becomes more serious due to the so-called water-fall noise phenomenon being perceived as if brighter and darker bands drift upwardly or downwardly.

The present invention solves the problems of the prior art. By means of reducing the channel length under the limit according to the stepper resolution, the present invention provides a display having a higher resolution than in the prior art and also provides a display which may be driven faster than in the prior art. Moreover, the present invention provides a display having higher aperture ratio and lower wire resistance, and eliminates the water-fall noise phenomenon by means of removing the protrusion part of the semiconductor pattern layer.

### SUMMARY OF THE INVENTION

A protrusion part of the pattern layer of which the area is relatively bigger is removed by forming a plating part on a surface of the pattern layer of which the area is relatively smaller between two pattern layers that are successively formed and overlapped. In addition, channel length of TFT is reduced by forming two plating parts between a source electrode and a drain electrode. The plating part may be formed by a electroless plating method and the plating material may be composed of at least one material selected from the group consisting of Ni, Co, Cu, Zn, Ag, Pt, and Pd.

It is desirable that the plating part formed on the surface of the relatively small pattern layer has enough thickness to cover the protrusion part completely. On the other hand, the two plating parts formed between the source electrode and the drain electrode must not contact each other.

In the case of forming the plating part on a data pattern layer in a four-mask manufacturing process, the previously mentioned problems of the prior art may be solved because the width or the thickness of the data pattern layer is increased, the channel length of a semiconductor pattern layer is reduced, and the protrusion part of the semiconductor pattern layer is removed without reduction of aperture ratio.

The plating part may be formed on various places other than the data pattern layer and in the case that the plating part is formed on other places, various effects may be expected other than solving the problem of the prior art above mentioned.

### BRIEF DESCRIPTION OF THE DRAWINGS

FIGS. 1-8 and 13-21 are cross-sectional views illustrating a manufacturing process of the TFT part of the TFT substrate according to an embodiment of the present invention;

FIG. 9 is a SEM picture showing the data pattern layer and the plating part of the experiment example according to an embodiment of the present invention;

FIG. 10 is a TEM picture showing the cross-section of the area A of the FIG. 9;

FIGS. 11 and 12 are a SEM picture and a TEM picture, respectively, showing the comparison experiment example according to a prior four-mask manufacturing process;

FIG. 22A is a SEM picture showing the data pattern layer and the plating part of the experiment example according to an embodiment of the present invention;

FIG. 22B is an FIB-SEM picture showing the cross-section of the area B of the FIG. 22A;

FIG. 23 is an FIB-SEM picture showing the cross-section of the channel part of the experiment example according to an embodiment of the present invention;

FIGS. 24A, 24B, and 24C are SEM pictures showing the relation between the plating time and the plating thickness of the experiment example according to an embodiment of the present invention;

FIG. 25 is a SEM picture showing another experiment example according to an embodiment of the present invention;

FIG. 26 is a SEM picture extending the area C of the FIG. 25;

FIG. 27 is an FIB-SEM picture showing the cross-section of the area C; and

FIGS. 28 and 29 are a SEM picture and a TEM picture, respectively, showing the comparison experiment example according to the prior art.

### DETAILED DESCRIPTION

Hereinafter, the present invention will be now described in detail with reference to the embodiments and the drawings.

### Embodiment 1

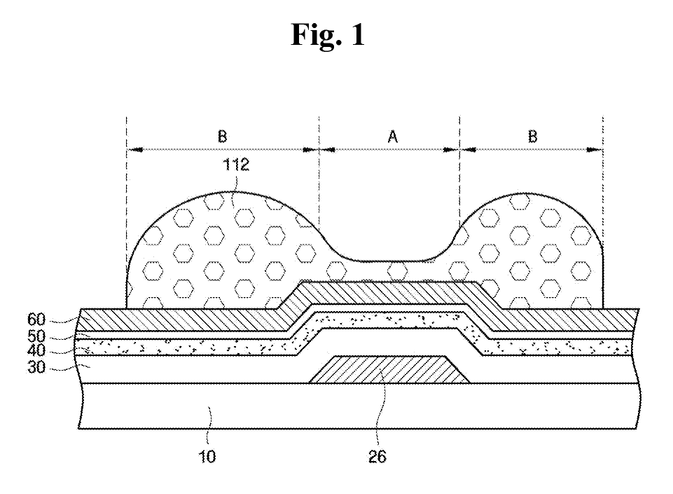

Hereinafter, an embodiment 1 of the present invention will be now described with reference to FIGS. 1-12. FIGS. 1-8 are cross-sectional views illustrating a manufacturing process of the TFT part of the TFT substrate according to the embodiment 1.

First, as shown in FIG. 1, after the gate conduction layer (not shown) is deposited on an insulating substrate 10 by a sputtering process, the gate pattern layer including a gate electrode 26 is formed by patterning the gate conduction layer through a photolithography process. Next, a gate insulating layer 30, a semiconductor layer 40, and an ohmic contact layer 50 are successively deposited on the insulating substrate 10 and on the gate pattern layer by a CVD (chemical vapor deposition) process in one example. Next, after depositing the data conduction layer 60 on the ohmic contact layer 50 by a sputtering process, for example, a photoresist pattern 112 corresponding to a data pattern layer (which will be formed from data conduction layer 60 in a subsequent process) is formed. When the photoresist pattern 112 is being formed, the part corresponding to a first region A over gate electrode 26 is made thinner than the part corresponding to a second region B by using a slit mask, a half-tone mask, or a reflow method.

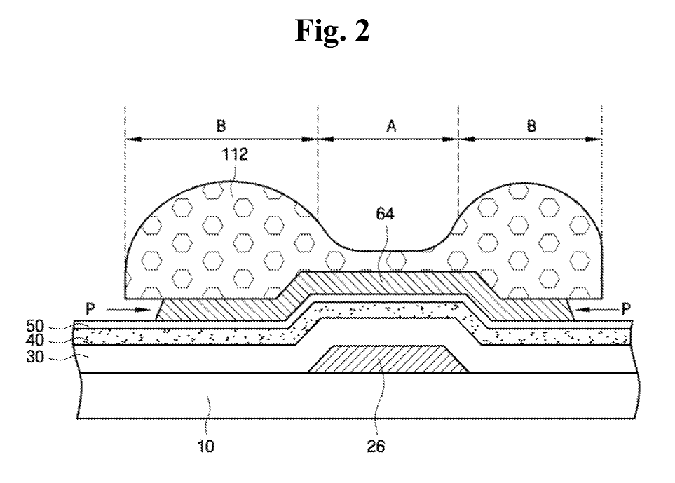

Next, as shown in FIGS. 1 and 2, an interim data pattern layer 64 is formed by wet etching the data conduction layer 60 using the photoresist pattern 112 as a mask. In the case of wet etching the data conduction layer 60 (which is an isotropic etching process), the interim data pattern layer 64 is retreated in some distance from the terminal of the bottom surface of the photoresist 112, as illustrated by arrow P in FIG. 2.

It is noted that although the data conduction layer 60 is illustrated in the drawings as a single layer, the data conduction layer 60 may be composed of multiple layers, and in that case a particular layer may relatively protrude or retreat according to the etching rate of each layer. In the case that the data conduction layer 60 is composed of a multi-layer (e.g., more than one layer) and wet etching and dry etching are selectively applied to the etching process of respective layers, the layer etched by wet etching may relatively retreat from the layer etched by dry etching.

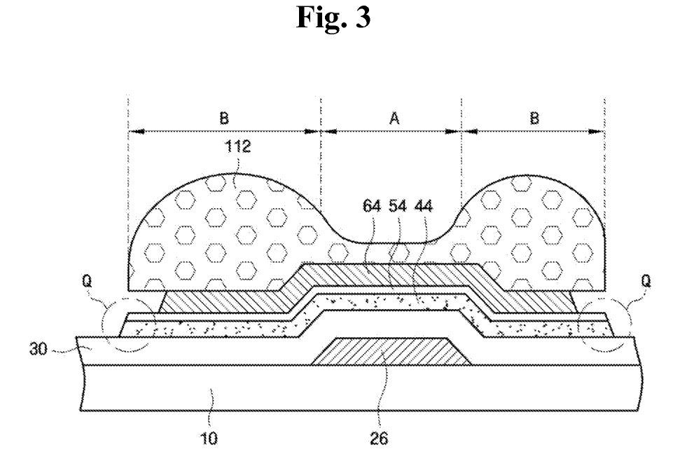

Next, as shown in FIGS. 2 and 3, an interim ohmic contact pattern layer 54 and semiconductor pattern layer 44 are formed by dry etching the ohmic contact layer 50 and the semiconductor layer 40, respectively, by using the photoresist pattern 112 as a mask. If dry etching, which is anisotropic etching, is used in this manner, when the interim ohmic contact pattern layer 54 and the semiconductor pattern layer 44 are formed, a protrusion part Q is left due to retreat of the interim data pattern layer 64. The length of the protrusion part Q (i.e., the length of ohmic contact pattern layer 54 and semiconductor pattern layer 44 beyond the end of the interim data pattern layer 64) may be from hundreds of nm to 1.5 μm, in one example.

It is noted that although the data conduction layer 60 is illustrated in the drawings as a single layer etched by wet etching, in the case that the data conduction layer 60 is formed as a multi-layer and the upper layer is etched by wet etching and lower layer is etched by dry etching, the protrusion part Q may include the dry etched lower layer of the data conduction layer 60, which does not retreat as much as the upper layer.

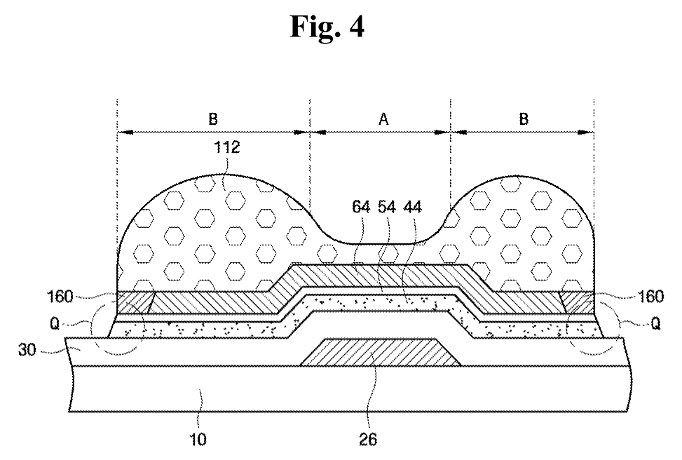

Next, as shown in FIG. 4, a plating part 160 is formed between the bottom surface of the photoresist pattern 112 and the top surface of the protrusion part Q. An electroless plating method may be used to form the plating part 160 and at least one selected from the group consisting of Ni, Co, Cu, Zn, Ag, Pt, and Pd may be used as plating material. Ni among the above has an advantage because it doesn't injure the photoresist, which is fragile to the alkali, since its plating solution is weak acid, of which the pH is about 4-5. Moreover, the conductivity of Ni is about 14.4 S·m-1(20° C.), it is similar to the conductivity of Mo and is higher than the same of Cr and Ti, which are used as a barrier layer of a metal wire, so that there is no problem in using Ni as material for a metal wire. Accordingly, the electroless plating method will be now described using Ni as a plating material example.

First, a defatting process using acid or neutral chemicals is performed on the TFT substrate of FIG. 3 to remove oxide layers, residue, and other pollutants, which may exist on the uncompleted TFT substrate of FIG. 3. Next, a soft etching process which etches the surface layer through chemicals, for instance, per lactate, lactate-hydrogen peroxide, etc., is performed to obtain adhesion between the interim data pattern layer 64 and Ni plating part 160. Next, a substitution process which substitutes an activator composed of palladium ion, etc. for the surface layer of the interim data pattern layer 64, is performed to commence an electroless Ni plating reaction. Next, the plating process for selectively forming the Ni plating part 160 in the space between the bottom surface of the photoresist pattern 112 and the top surface of the protrusion part Q is performed by using electroless Ni plating solution, which is an aqueous solution comprising: a Ni salt, for instance, nickel sulfate, nickel chloride, nickel sulfamate, etc.; a reducing agent, for instance, sodium hypophosphite, potassium hypophosphite, etc.; a complex agent, for instance, lactic acid, citric acid, malic acid, glycolic acid, glucosan, etc.; an accelerator, for instance, acetic acid, formic acid, propionic acid, malonic acid, etc.; and a tranquilizer, for instance, a heavy metal like lead. At this step, it is desirable that the top surface of the interim ohmic contact pattern layer 54 is not exposed out of the plating part 160 (i.e., the top surface of the interim ohmic contact pattern layer 54 is completely covered by plating part 160) by suitably controlling the plating process parameters, such as the activator density, the plating solution substances, the plating time, etc. Because the length of the protrusion part Q is between about hundreds of nm˜1.5 μm and the growth rate of the plating thickness is about 200˜1000 Å/min, it takes about several minutes to tens of minutes to plate. The plating time must be optimized according to process and design conditions.

It is noted that the defatting process and the soft etching process among the above processes may be omitted, and other processes not mentioned above may be added. A further detailed explanation about the plating process is omitted.

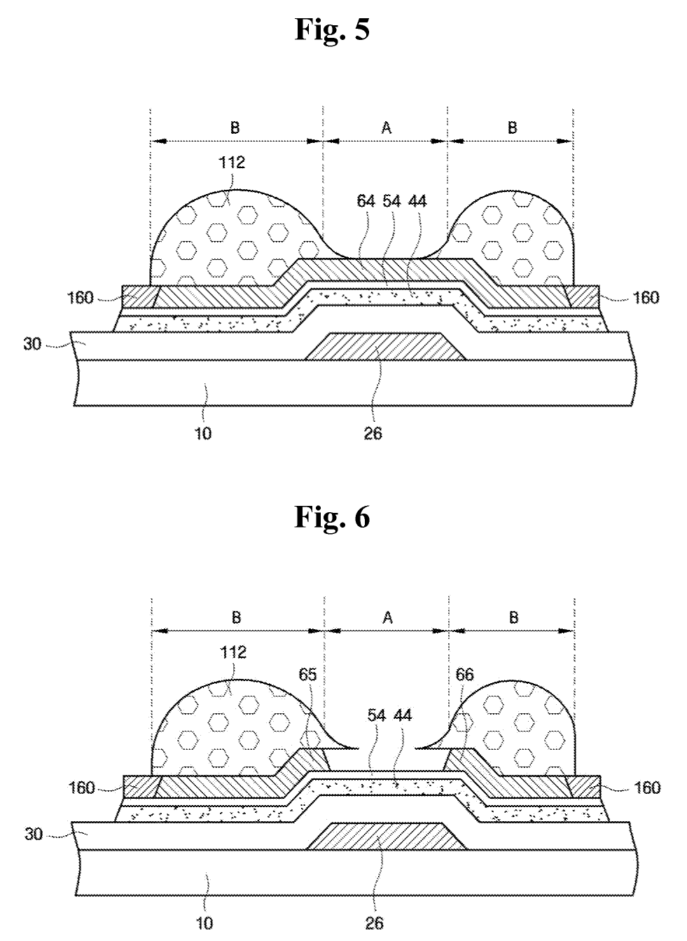

Next, as shown in FIGS. 4 and 5, the upper part of the photoresist pattern 112 is removed by an etch-back process and the residue of the photoresist on the top surface of the interim data pattern layer 64 corresponding to the first region A is removed by an ashing process so that the top surface of the interim data pattern layer 64 corresponding to the first region A is exposed. It is important in this process that the process condition is controlled such that the top surface of the interim data pattern layer 64 adjacent to the plating part 160 is not exposed out of the photoresist pattern 112 to prevent undesired etching of the interim data pattern layer 64 in the next process step. In addition, there may be a need that etch-back rate of the photoresist pattern 112 is controlled for the plating part 160 not to be exposed out of the photoresist pattern 112 according to the etching property between the interim data pattern layer 64 and the plating part 160

Next, as shown in FIGS. 5 and 6, a data pattern layer 65, 66 (e.g., including a source electrode 65 and a drain electrode 66) is formed by removing the part of the interim data pattern layer 64 corresponding to the first region A through wet etching. Because the case that the interim data pattern layer 64 is not a single layer and a dry etching process, not a wet etching, is applied, has previously been explained, the detailed description about this case is omitted here.

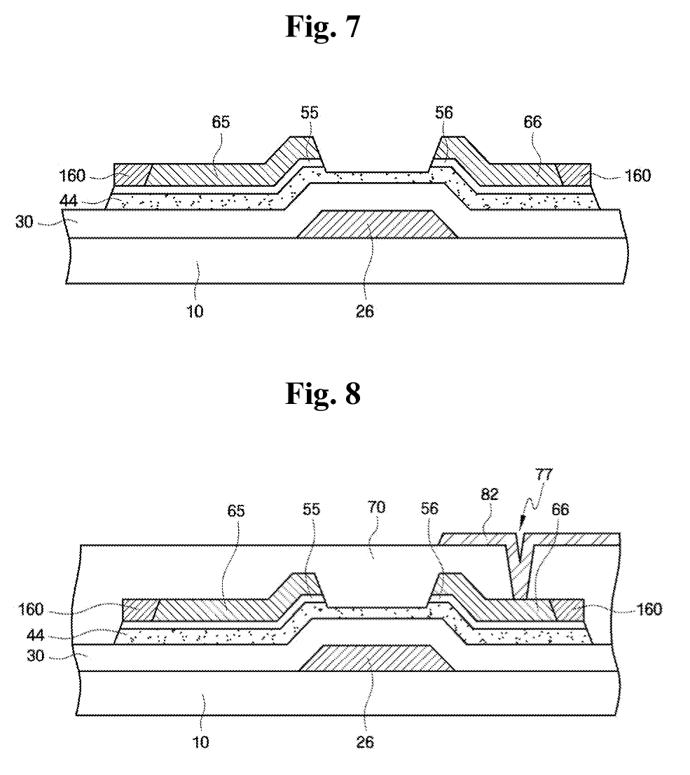

Next, as shown in FIGS. 6 and 7, an ohmic contact pattern layer 55, 56 is formed by etching the part of the interim ohmic contact pattern layer 54 corresponding to the first region A through dry etching. In this process, it is important that the part of the interim ohmic contact pattern layer 54 corresponding to the first region A is fully removed while also minimizing the etched thickness of the semiconductor pattern layer 44 at the same time. Two kinds of processes may be applied to the etching process of the interim ohmic contact pattern layer 54. The first is dry etching the interim ohmic contact pattern layer 54 by using the data pattern layer 65, 66 as a mask after removing the photoresist pattern 112 in FIG. 6 and the second is dry etching the interim ohmic contact pattern layer 54 by using the photoresist pattern 112 as a mask upon maintaining the photoresist pattern 112 in FIG. 6. In the case of the second process, the terminal of the data pattern layer 65, 66 and the ohmic contact pattern layer 55, 56 may not be coincident or aligned with each other and may form a shape of stairs. Generally, the first process is used and FIG. 7 illustrates the structure based on this process.

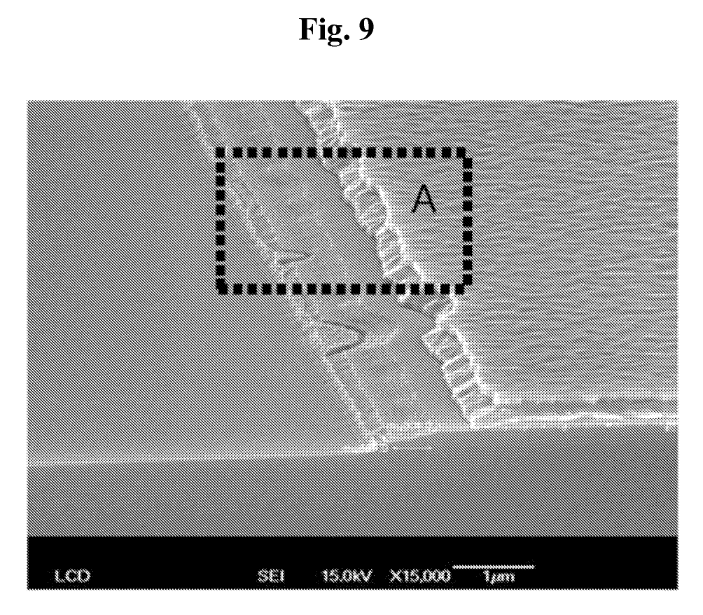

Next, as shown in FIG. 8, a protection layer 70 is formed on the data pattern layer 65, 66 and on the plating part 160, and a contact hole 77 exposing the drain electrode 66 is made by etching the protection layer 70. Then, a transparent pattern layer including a pixel electrode 82 is formed on the protection layer 70. The pixel electrode 82 is electrically connected to the drain electrode 66 through the contact hole 77.

The TFT substrate according to the above described embodiment increases design margin about the semiconductor pattern layer 44, ohmic contact pattern layer 55, 56, and the data pattern layer 65, 66 because the conductive plating part 160 in contact with the data pattern layer 65, 66 is formed on the protrusion part Q of the semiconductor layer, which is especially generated in the four-mask manufacturing process. Accordingly, a design having higher aperture ratio and lower resistance compared to the prior art may be possible. Moreover, the water-fall noise phenomenon may be suppressed because the protrusion part Q is not exposed to an ambient light due to the plating part 160.

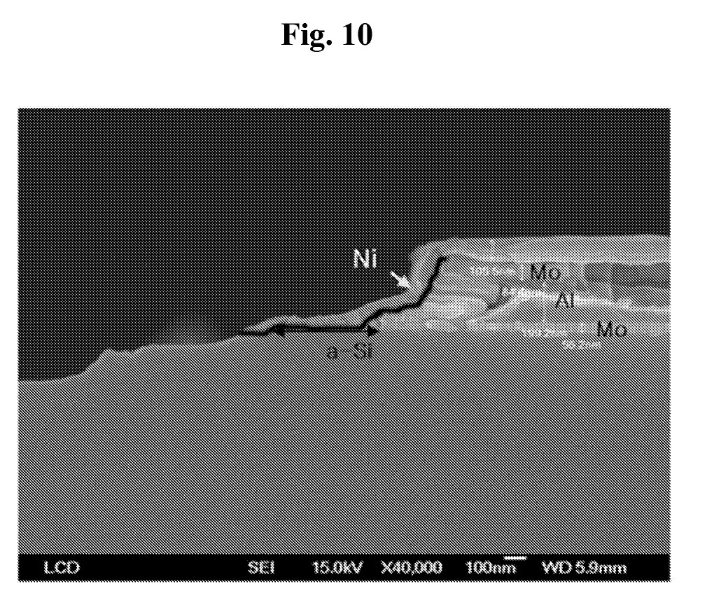

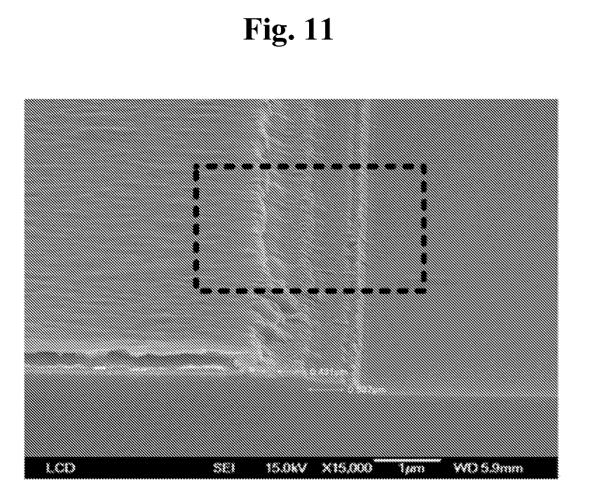

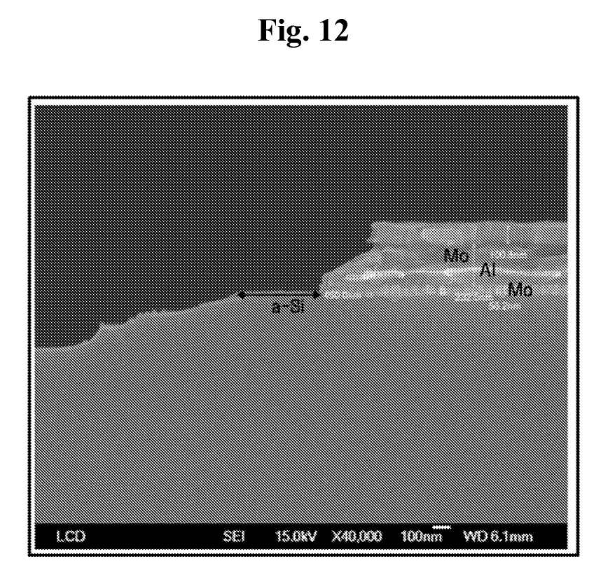

FIG. 9 is a SEM (Scanning Electron Microscope) picture showing the data pattern layer and the plating part of the experiment example according to the embodiment 1, and FIG. 10 is a TEM (Transmission Electron Microscope) picture showing the cross-section of the area A of the FIG. 9. FIGS. 11 and 12 are respectively a SEM picture and a TEM picture, showing the comparison experiment example according to the prior four-mask manufacturing process.

The present experiment example is the case that the data pattern layer is a multi-layer composed of Mo/Al/Mo triple-layer. As shown in FIGS. 9 and 10, it is noticeable that the protrusion part of the semiconductor pattern layer a-Si and lateral surface of the data pattern layer Mo/Al/Mo are covered by the plating part Ni, different from the comparison experiment example shown in FIGS. 11 and 12. The TFT substrate of the FIGS. 9 and 10 is the case that the plating part Ni is formed thinly as its thickness is about 100 nm. Thinly forming the plating part like this is disadvantageous to increasing aperture ratio and decreasing resistance of the data pattern layer, but there is no problem in removing the water-fall noise phenomenon because ambient light irradiating the semiconductor pattern layer can be fully blocked by the plating part. Meanwhile, appearing in the FIG. 10 as if the plating part Ni is grown on the surface of the semiconductor pattern layer a-Si, not just on the data pattern layer Mo/Al/Mo, this is the phenomenon generated since the plating part is grown like tail because the aluminum layer Al, of which the ionization tendency is very big, gives the semiconductor pattern layer a-Si electrons. The shape of the plating part may be varied according to the electroless plating process conditions.

### Embodiment 2

Hereinafter, an embodiment 2 of the present invention will be now described with reference to FIGS. 1-3 and 13-17. For convenience of explanation, the components having the same function as each component illustrated in the drawings of the embodiment 1 are indicated by the same symbol and the explanation about the same structure and the same process will be omitted. The embodiment 2 will be described, focusing on the differences.

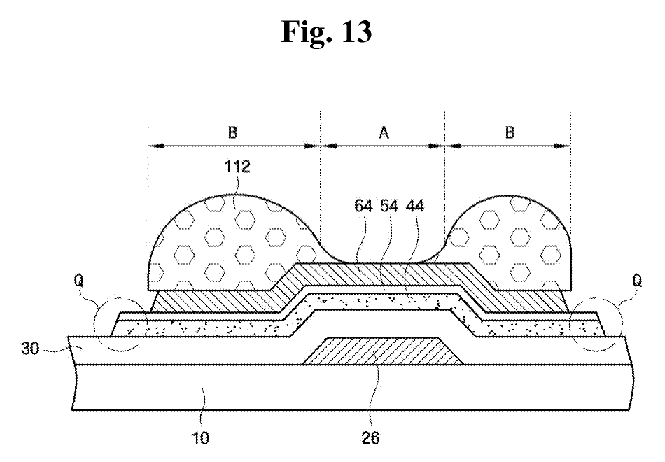

After finishing the same processes as the embodiment 1 illustrated in FIGS. 1-3 in the first instance, as shown in FIG. 13, the part of the interim data pattern layer 64 corresponding to the first region A is exposed by etch-back and ashing of the photoresist pattern 112.

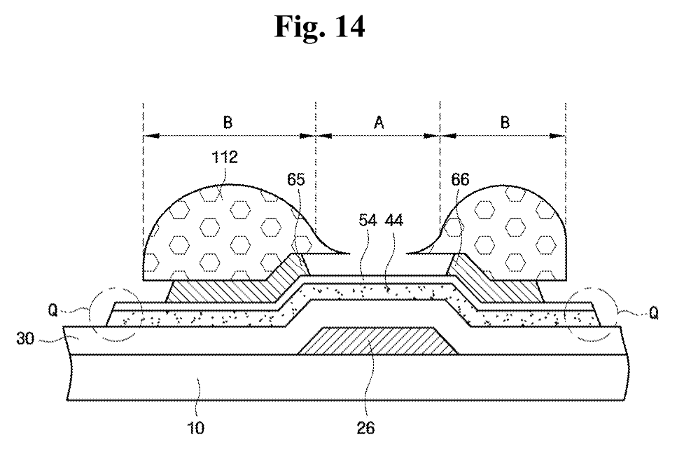

Next, as shown in FIGS. 13 and 14, the data pattern layer 65, 66 including the source electrode and drain electrode is formed by etching the part of the interim data pattern layer 64 corresponding to the first region A through wet etching. In this case, the protrusion part Q is formed longer than the embodiment 1 because the lateral surface of the data pattern layer 65, 66 adjacent to the protrusion part Q is etched one more time.

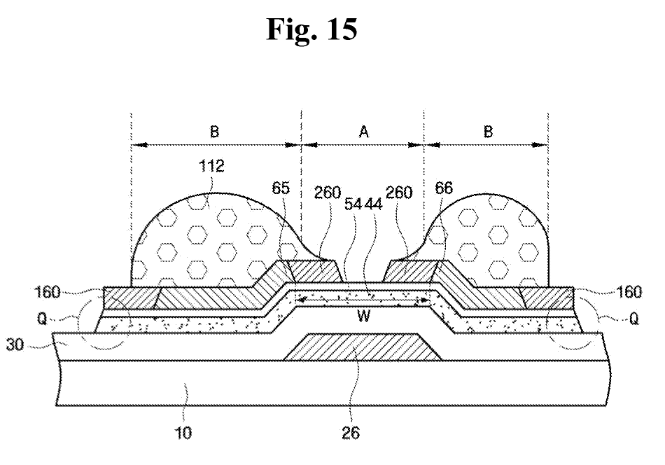

Next, as shown in FIG. 15, plating parts 160, 260 are formed at two lateral surfaces or ends of the data pattern layer 65, 66 through an electroless Ni plating method. The plating process of the present embodiment is basically the same as in embodiment 1, but the process condition must be controlled according to the plating thickness determined by considering the exposed width W of the semiconductor pattern layer 44 and the length of the protrusion Q before the plating process. It is desirable that the top surface of the protrusion part Q is covered by outside plating part 160 and the pair of inside plating parts 260 must not make contact with each other. The plating thickness is suitably selected by considering that the general exposed width of the semiconductor pattern layer 44 and the length of the protrusion part Q.

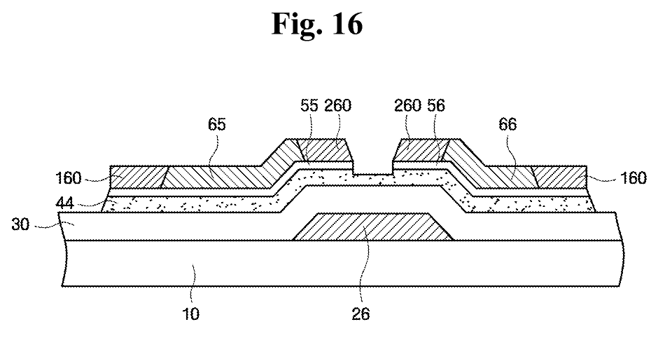

After finishing the plating process, as shown in FIGS. 15 and 16, the ohmic contact pattern layer 55, 56 is formed by etching the interim ohmic contact pattern layer 54 through dry etching. In this case, two processes are also possible; the first is dry etching the interim ohmic contact pattern layer 54 using the data pattern layer 65, 66 and the plating part 160, 260 as a mask after removing the photoresist pattern 112 of the FIG. 15, and the second is dry etching the interim ohmic contact pattern layer 54 using the photoresist pattern 112 as a mask, upon maintaining the photoresist pattern 112 of the FIG. 15. The FIG. 16 is illustrated based on the first process. In the case of the second process, the ohmic contact pattern layer may protrude out of the inside plating part to some degree.

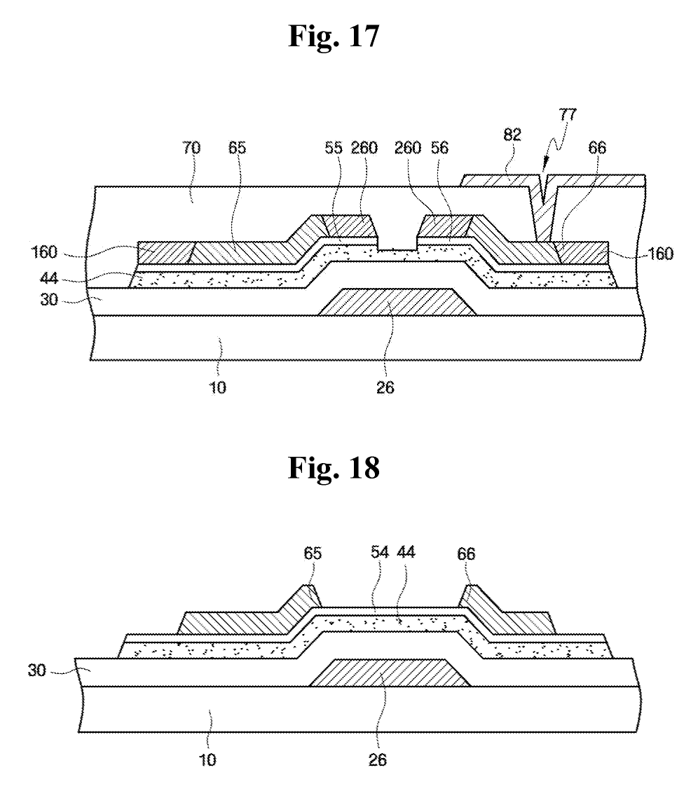

The explanation about the process of the FIG. 17 is omitted because it is not different from the process of the FIG. 8 of the embodiment 1.

The TFT substrate according to the above described embodiment has a shorter channel length by as much as the thickness of the inside plating part 260 in comparison with the prior art. Accordingly, the ion current of TFT channel can be increased beyond the limit according to the stepper resolution. Moreover, the same effects with the embodiment 1 can be acquired since the protrusion part Q of the semiconductor pattern layer 44, which is generated in the prior four-mask manufacturing process, may be removed by the outside plating part 160.

### Embodiment 3

Hereinafter, an embodiment 3 of the present invention will be now described with reference to FIGS. 1-3, 13-14 and 18-29. For convenience of explanation, the components having the same function as each component illustrated in the drawings of the embodiments 1 and 2 are indicated by the same symbol and the explanation about the same structure and the same process will be omitted. The embodiment 3 will be described, focusing on the differences.

After finishing the same processes as embodiment 2 illustrated in FIGS. 1-3 and 13-14 in the first instance, as shown in FIG. 18, the photoresist pattern 112 is removed.

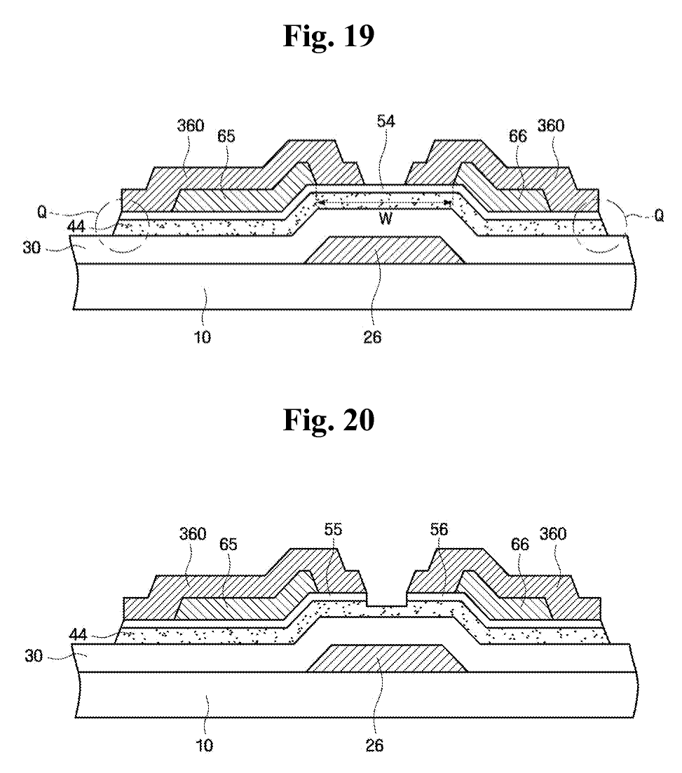

Next, as shown in FIG. 19, a plating part 360 is formed on the two lateral surfaces and top surface of the data pattern layer 65, 66 through the electroless Ni plating method. The plating process of the present embodiment is basically the same as in the embodiments 1 and 2, but the process condition must be controlled according to the plating thickness determined by considering not only the exposed width W of the semiconductor pattern layer 44 and the length of the protrusion Q, but also the thickness of the plating part 360 formed on the top surface of the data pattern layer 65, 66. The thickness of the data pattern layer 65, 66 may be controlled by considering the thickness of the plating part 360 formed on the top surface of the data pattern layer 65, 66. For reference, the growth profile ratio, which is expressed as a ratio of the thickness T1 of the plating part 360 formed on the top surface of the data pattern layer 65, 66 to the thickness T2 of the plating part 360 formed on the lateral surface of the data pattern layer 65, 66, T1/T2=0.8˜1.2. In other words, the growth profile ratio is close to 1:1 in one example.

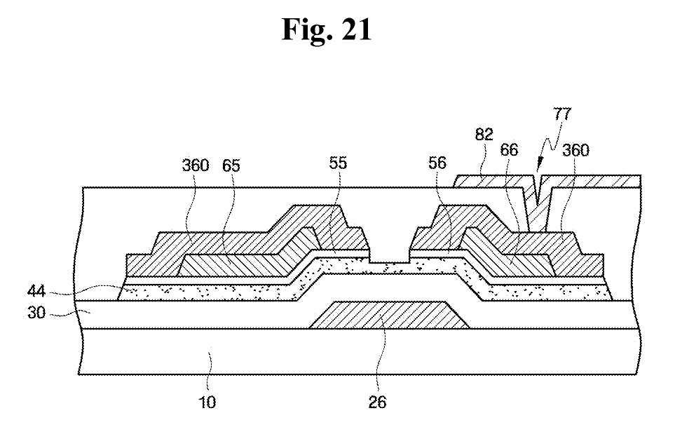

Next, as shown in FIGS. 19 and 20, the ohmic contact pattern layer 55, 56 is formed by dry etching the interim ohmic contact pattern layer 54 using the plating part 360 as a mask. The explanation about the process of the FIG. 21 is omitted because it is not different from the process of the FIG. 8 of the embodiment 1.

The TFT substrate according to the above described embodiment may obtain all effects being obtained in the embodiment 2. In addition to it, the wire resistance may be more reduced in comparison with the embodiments 1 and 2 because the thickness of the wire is increased by as much as the thickness of the plating part.

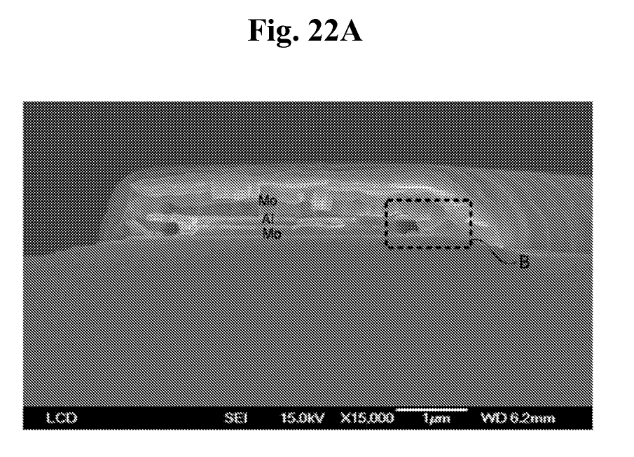

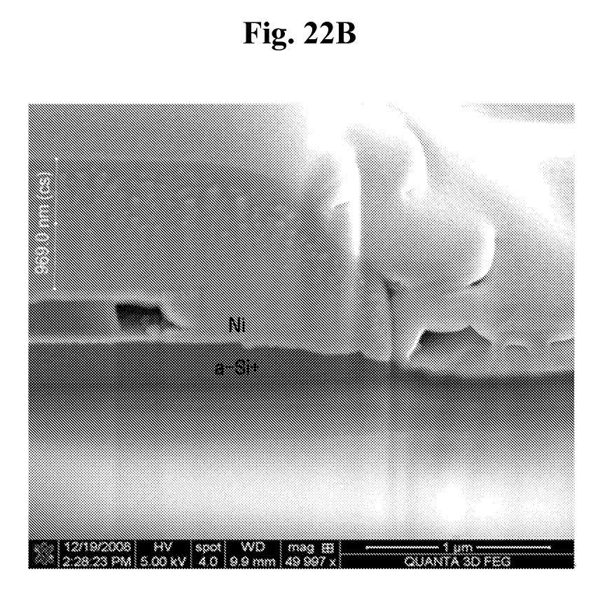

FIG. 22A is a SEM picture showing the data pattern layer and the plating part of the experiment example according to the embodiment 3, and FIG. 22B is an FIB-SEM (Focus Ion Beam-Scanning Electron Microscope) picture showing the cross-section of the area B of the FIG. 22A.

The present experiment example is the case that the data pattern layer is a multi-layer composed of Mo/Al/Mo triple-layer and the thickness of the plating part Ni is about 1 μm. It is certified that the interface between the ohmic contact pattern layer a-Si+ and the plating part Ni is well formed.

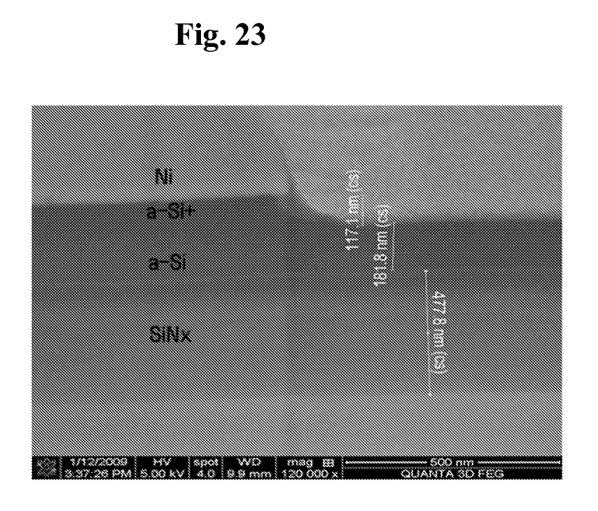

FIG. 23 is an FIB-SEM picture showing the cross-section of the channel part of the experiment example according to the embodiment 3.

The result that the ohmic contact pattern layer a-Si+ is dry etched using the plating part Ni as a mask is shown.

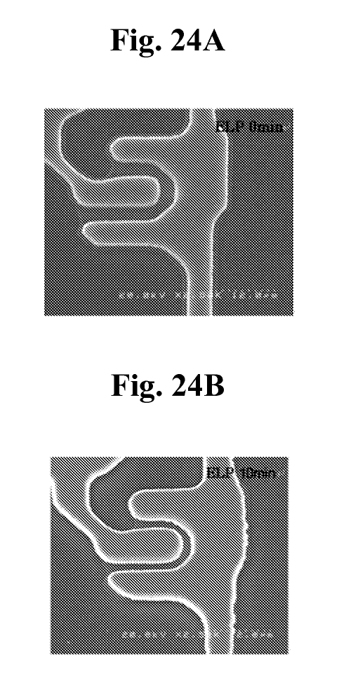

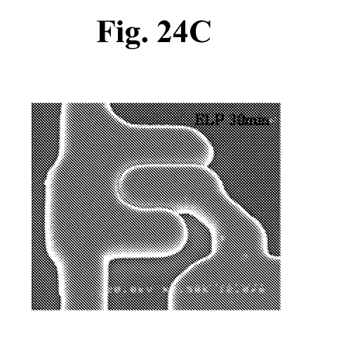

The below [Table 1] is the experiment result measuring plating thickness, channel length, and wire width according to plating time of the TFT substrate according to the above described embodiment 3, and FIGS. 24A, 24B, and 24C are SEM pictures corresponding to respective experiment examples.

As indicated by the [Table 1] and FIGS. 24A, 24B, and 24C, if the plating time is long enough, the channel length may be reduced down to 0.01 μm and the wire width is increased up to about double a previous width.

TABLE 1

| | ELP 0 min | ELP 10 min | ELP 30 min |
|---|---|---|---|
| Plating part thickness (Å) | 0 | 8300 | 22400 |
| Channel Length (um) | 2.89 | 1.50 | 0.01 |
| Wire width (um) | 4.80 | 6.19 | 8.58 |

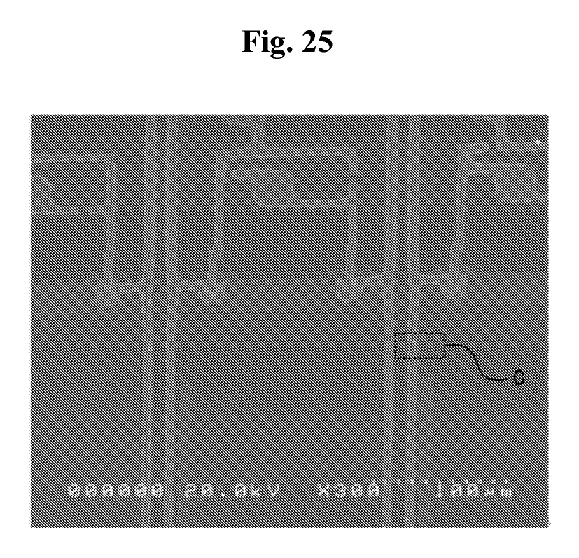

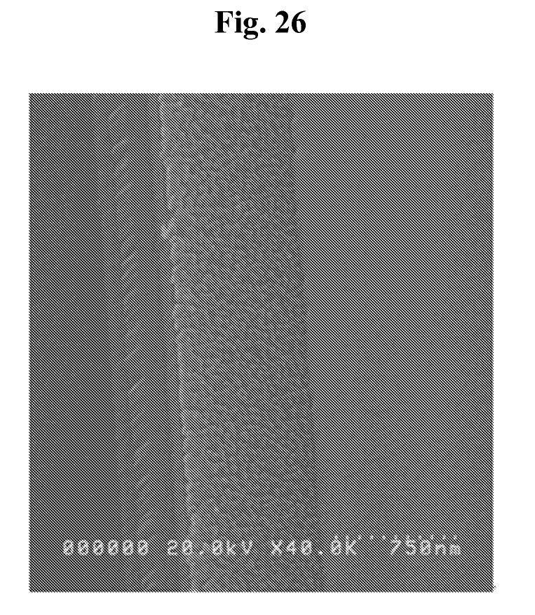

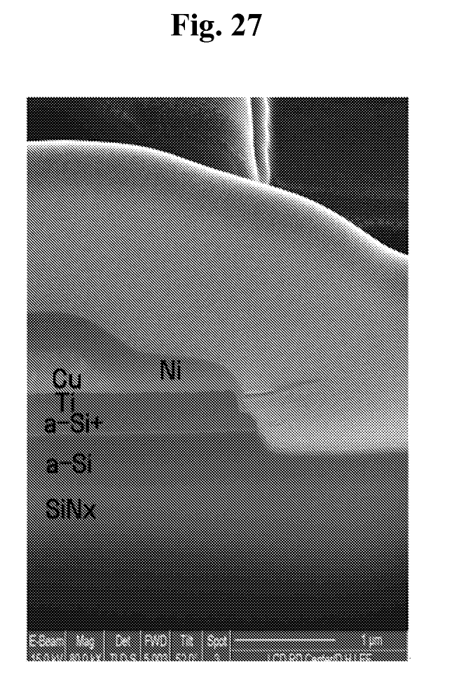

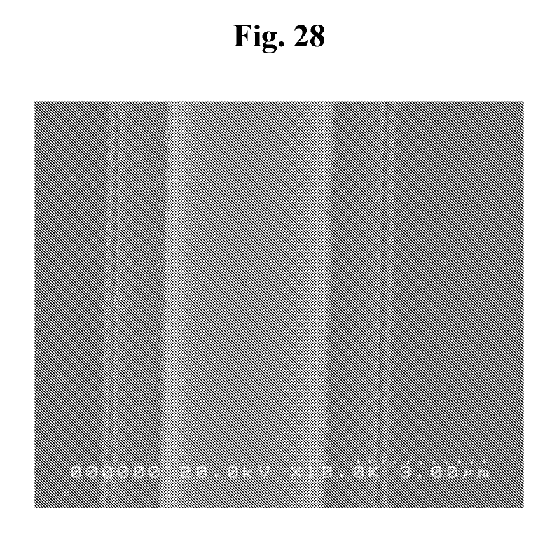

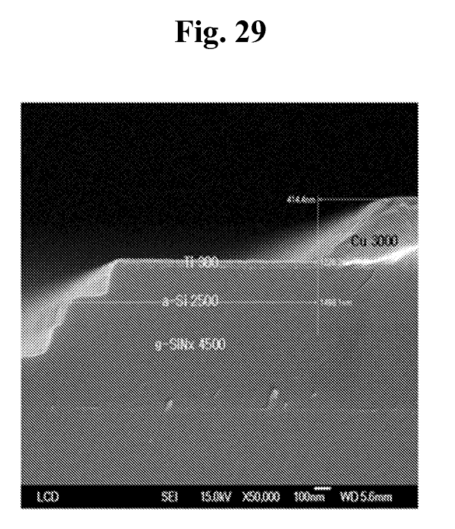

FIG. 25 is a SEM picture showing another experiment example according to the embodiment 3, FIG. 26 is a SEM picture extending the area C of the FIG. 25, and FIG. 27 is an FIB-SEM picture showing the cross-section of the area C. FIGS. 28 and 29 are respectively a SEM picture and a TEM picture, showing the comparison experiment example according to the prior art.

The present experiment example is the case that the Cu/Ti double-layer is used as the data conduction layer. The copper layer Cu is etched by wet etching and the titanium layer Ti is etched by dry etching. As shown in FIGS. 25-27, the copper layer Cu, which is an upper layer, relatively retreats from the titanium layer Ti, which is the lower layer, and the plating part Ni covers the top surface of the copper layer Cu and the titanium layer Ti. It is shown that the plating part Ni is not grown enough toward the lateral direction of titanium layer Ti because the thickness of the titanium layer Ti is about 300 Å. In the case of the present experiment example, the ohmic contact pattern layer a-Si+ and the semiconductor pattern layer a-Si almost don't protrude out of the titanium layer Ti, which is a data pattern layer, different from the Mo/Al/Mo triple-layer, because the titanium layer Ti, the ohmic contact layer a-Si+, and the semiconductor layer a-Si are all dry-etched and the titanium layer Ti, the ohmic contact pattern layer a-Si+, and the semiconductor pattern layer a-Si form the protrusion part, which relatively protrudes from the copper layer Cu, together. It is indicated through the present experiment example that the present invention is effective at solving the protrusion problem of a wire generated due to the difference between isotropy of wet etching and anisotropy of dry etching or generated due to the difference of etching rate between each layer in multi-layered wire.

In addition to the above described embodiments, the embodiment that one part of the plating part, which is formed on the lateral surfaces of the drain electrode and the source electrode facing each other, and the other part of the plating part are formed respectively through two times of plating processes, not once, is also possible and the embodiment that the plating part is only formed on the lateral surfaces of the drain electrode and the source electrode facing each other is also possible. Detailed explanation about these embodiments will be omitted since referring to the above described embodiment, the skilled in the art may implement these embodiments without difficulty. If there is a need to make the thickness of individual plating parts independent, forming the plating part respectively through two process steps may have practical usage.

Though all of the above described embodiments are explained based on the four-mask manufacturing process, the concept of the present invention can be applied to a three-mask manufacturing process, a five-mask manufacturing process, or more than five-mask manufacturing process. In addition, though all of the above described embodiments are explained based on the plating part being formed on the data pattern layer, the concept of the present invention can be applied to various layers, such as a gate pattern layer, which in this case the process may be applied to remove the protrusion part of a multi-layer wire (not for reducing the channel length) and/or to remove the protrusion of the semiconductor pattern layer. In addition, though all of the above described embodiments are explained based on the plating part being formed on the protrusion part, forming the plating part under the protrusion part is also possible because occurrence of the protrusion is just dependent on the process and not on the location or the substance of a particular layer. For example, in the case that the wet etched layer is located directly below the dry etched layer, or the etching rate of the lower layer is relatively higher than the etching rate of the upper layer, the lower layer relatively retreats from the upper layer. In this case, the plating part would be formed under the protrusion part.

The insulating substrate, the gate conduction layer, the gate insulating layer, the ohmic contact layer, the semiconductor layer, the data conduction layer, the protection layer, and the transparent conduction layer of the above described embodiments may be formed as a single layer or multi-layer, and all of structures and substances known as being used at corresponding layers in the art may be applied only if not adverse to the concept of the present invention. In fact, all of structures and substances that may be developed in the future may be applied only if it is not adverse to the concept of the present invention as a matter of course. In addition, though the above described embodiments are all so-called bottom gate structures that the gate electrode is located under the semiconductor pattern layer, the concept of the present invention may be applied to the so-called top gate structure that the gate electrode is located on the semiconductor pattern layer. In addition, though above described embodiments are the cases that the concept of the present invention is applied to the liquid crystal display device, the concept of the present invention may be applied to all display devices comprising a metal wire or a thin film transistor, as organic light emitting diode device, as a matter of course.

Furthermore, though embodiments are described as if the first region A clearly corresponds to the TFT channel and the second region B clearly corresponds to the source/drain, and the two regions are clearly divided, it is for convenience of explanation, and the skilled in the art may know through the above described embodiments that the border of these two regions may not be clearly discriminated and the two regions may not exactly correspond to the TFT channel and the source/drain respectively.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A display device, comprising:
a transparent insulating substrate;
a first pattern layer formed on the transparent insulating substrate;
a second pattern layer formed on the top surface or the bottom surface of the first pattern layer; and
a plating part formed on at least one surface of the second pattern layer,
wherein an outline of the second pattern layer is wholly located in an area made by the first pattern layer, when the display device is projected from a top view.

2. The display device of claim 1, wherein at least a part of the plating part is located in an area made by an outline of the first pattern layer and the outline of the second pattern layer, when the display device is projected from the top view.

3. The display device of claim 1, wherein an area made by an outline of the first pattern layer and the outline of the second pattern layer is wholly located in an area made by the plating part.

4. The display device of claim 1, wherein the plating part is formed on a top surface and a lateral surface of the second pattern layer.

5. A display device manufacturing method, comprising:
successively forming a first pattern layer and a second pattern layer without an intermediate layer; and
adhesively forming a plating part on at least one surface of the second pattern layer,
wherein an outline of the second pattern layer is wholly located in an area made by the first pattern layer.

6. The display device manufacturing method of claim 5, wherein the first pattern layer is formed by dry etching and the second pattern layer is formed by wet etching.

7. The display device manufacturing method of claim 5, wherein the plating part is formed by electroless plating and is composed of at least one material selected from the group consisting of Ni, Co, Cu, Zn, Ag, Pt, and Pd.
